(19) United States
(12) Patent Application Publication
(10) Pub. No.: US 2016/0027785 A1
(43) Pub. Date: Jan. 28, 2016

(54) SEMICONDUCTOR DEVICE AND METHOD FOR MANUFACTURING SAME

(71) Applicant: PS4 LUXCO S.A.R.L., Luxembourg (LU)

(72) Inventor: Hiroyuki Fujimoto, Tokyo (JP)

(21) Appl. No.: 14/761,206

(22) PCT Filed: Jan. 15, 2014
(86) PCT No.: PCT/JP2014/050503

§ 371 Date: Jul. 15, 2015

(30) Foreign Application Priority Data
Jan. 16, 2013 (JP) 2013-005255

(51) Int. Cl. H01L 27/108; H01L 29/78

(52) U.S. Cl. CPC H01L 27/10808; H01L 29/7827; H01L 27/10855; H01L 27/10876

(57) ABSTRACT

One semiconductor device includes a semiconductor substrate having a plurality of first trenches formed to extend in the first direction, an embedded gate electrode embedded in a lower part of each of the first trenches with a gate insulating film there between, an embedded insulating film embedded in each of the first trenches, said embedded insulating film being on the embedded gate electrode, an isolating insulating film, which is provided on the embedded insulating film, and which has a width smaller than that of the first trenches, a diffusion region that is provided on the semiconductor substrate by being adjacent to the first trenches, a conductive layer in contact with the diffusion region, and a contact plug in contact with the conductive layer. The conductive layer is disposed also on the embedded insulating film on the embedded gate electrode, and is partitioned by means of the isolating insulating film.

### TECHNICAL FIELD

(Disclosure regarding related application)

The present invention is based on priority to Japanese Patent Application: JP 2013-005255 (filed Jan. 16, 2013), the disclosure of which is incorporated in its entirety into the present document by way of reference. The present invention relates to a semiconductor device provided with a transistor having an embedded gate electrode, and to a method for manufacturing same.

### BACKGROUND

In a conventional semiconductor device provided with a transistor having an embedded gate electrode (word line) which is embedded, with a gate insulating film interposed, in a trench formed in a semiconductor substrate, a capacitance contact plug connected to a capacitor is connected (including connection by way of silicide) to a diffusion region formed on the surface of the semiconductor substrate between an element isolation region and the embedded gate electrode. For example, Patent Document 1 describes a semiconductor device in which a contact plug (42) is connected to an impurity diffusion region (28).

### PATENT DOCUMENTS

Patent Document 1: JP 2012-99775 A

### SUMMARY OF THE INVENTION

### Problem to be Solved by the Invention

The disclosure of the abovementioned patent document is incorporated into the present document by way of reference. The following analysis is submitted by the inventor of this application.

With the semiconductor device described in Patent Document 1 (FIG. 1 and FIG. 2), however, the contact plug (42) can be connected only to part of the surface of the impurity diffusion region (28) because of the layout, so there is a possibility of connection defects occurring between the contact plug (42) and the impurity diffusion region (28) due to manufacturing errors.

### Means for Solving the Problem

According to a first aspect of the present invention, a semiconductor device is characterized in that it is provided with: a semiconductor substrate having a plurality of first trenches formed extending in a first direction; an embedded gate electrode which is embedded at the lower part of the first trenches with a gate insulating film interposed; an embedded insulating film which is embedded on the embedded gate electrode in the first trenches; an isolation insulating film which is provided on the embedded insulating film and has a smaller width than the first trenches; a diffusion region which is provided adjacent to the first trenches on the semiconductor substrate; a conduction layer in contact with the diffusion region; and a contact plug in contact with the conduction layer, the conduction layer also being disposed on the embedded insulating film on the embedded gate electrode and also being partitioned by the isolation insulating film.

According to a second aspect of the present invention, a method for manufacturing a semiconductor device is characterized in that it comprises the following steps: a step in which a diffusion region is formed on the upper part of a semiconductor substrate; a step in which a plurality of first trenches which extend in a first direction and have a greater depth than the diffusion region are formed on the semiconductor substrate including the diffusion region; a step in which an embedded gate electrode which is embedded with a gate insulating film interposed is formed inside the first trenches; a step in which the upper part of the embedded gate electrode inside the first trenches is removed; a step in which an embedded insulating film is deposited on the diffusion region including the embedded gate electrode inside the first trenches, in such a way that the first trenches are not filled; a step in which an isolation insulating film is deposited on the embedded insulating film in such a way that the first trenches are filled; a step in which the upper part of the isolation insulating film is selectively removed until the embedded insulating film becomes apparent; a step in which the upper part of the embedded insulating film is selectively removed until the diffusion region becomes apparent while the isolation insulating film remains; a step in which a plurality of conduction layers partitioned by means of the isolation insulating film are formed on the diffusion region including the embedded insulating film; a step in which a first interlayer insulating film is formed on the conduction layer including the isolation insulating film; a step in which a first contact hole communicating with a first conduction layer from among the plurality of conduction layers is formed in the first interlayer insulating film; and a step in which a contact plug is formed inside the first contact hole.

### Advantage of the Invention

According to the present invention, a conduction layer on a diffusion region partitioned by an isolation insulating film is present up to a region on an embedded gate electrode, and as a result it is possible to broaden the contact area between a contact plug and the diffusion region through the conduction layer. Furthermore, according to the present invention, the conduction layer on the diffusion regions is partitioned by the isolation insulating film, and as a result it is possible to enlarge the short-circuit margin between the diffusion regions.

### BRIEF DESCRIPTION OF THE FIGURES

FIG. 1 is a view in cross section between A-A′ in FIG. 2 schematically showing the configuration of a semiconductor device according to Mode of Embodiment 1 of the present invention;

FIG. 2 is a partial plan view (corresponding to FIG. 1) schematically showing the configuration of the semiconductor device according to Mode of Embodiment 1 of the present invention;

FIG. 3 is a partial plan view (corresponding to FIG. 4) showing part of a step in a method for manufacturing a semiconductor device according to Mode of Embodiment 1 of the present invention;

FIG. 4 is a view in cross section (corresponding to FIG. 3) between B-B′ in FIG. 3 showing part of a step in the method for manufacturing a semiconductor device according to Mode of Embodiment 1 of the present invention;

FIG. 5 is a view in cross section (corresponding to between B-B′ in FIG. 3) which is a continuation of FIG. 4 showing part of a step in the method for manufacturing a semiconductor device according to Mode of Embodiment 1 of the present invention;

FIG. 6 is a partial plan view (corresponding to FIG. 7) which is a continuation of FIG. 5 showing part of a step in the method for manufacturing a semiconductor device according to Mode of Embodiment 1 of the present invention;

FIG. 7 is a view in cross section (corresponding to FIG. 6) of between C-C′ in FIG. 6 showing part of a step in the method for manufacturing a semiconductor device according to Mode of Embodiment 1 of the present invention;

FIG. 8 is a view in cross section (corresponding to between C-C′ in FIG. 6) which is a continuation of FIG. 6 and FIG. 7 showing part of a step in the method for manufacturing a semiconductor device according to Mode of Embodiment 1 of the present invention;

FIG. 9 is a view in cross section (corresponding to between B-B′ in FIG. 6) which is a continuation of FIG. 8 showing part of a step in the method for manufacturing a semiconductor device according to Mode of Embodiment 1 of the present invention;

FIG. 10 is a view in cross section (corresponding to between C-C′ in FIG. 6 and corresponding to FIG. 11) which is a continuation of FIG. 9 showing part of a step in the method for manufacturing a semiconductor device according to Mode of Embodiment 1 of the present invention;

FIG. 11 is a view in cross section (corresponding to between B-B′ in FIG. 6 and corresponding to FIG. 10) which is a continuation of FIG. 9 showing part of a step in the method for manufacturing a semiconductor device according to Mode of Embodiment 1 of the present invention;

FIG. 12 is a view in cross section (corresponding to between C-C′ in FIG. 6 and corresponding to FIG. 13) which is a continuation of FIG. 10 and FIG. 11 showing part of a step in the method for manufacturing a semiconductor device according to Mode of Embodiment 1 of the present invention;

FIG. 13 is a view in cross section (corresponding to between B-B′ in FIG. 6 and corresponding to FIG. 12) which is a continuation of FIG. 10 and FIG. 11 showing part of a step in the method for manufacturing a semiconductor device according to Mode of Embodiment 1 of the present invention;

FIG. 14 is a view in cross section (corresponding to between C-C′ in FIG. 6 and corresponding to FIG. 15) which is a continuation of FIG. 12 and FIG. 13 showing part of a step in the method for manufacturing a semiconductor device according to Mode of Embodiment 1 of the present invention;

FIG. 15 is a view in cross section (corresponding to between B-B′ in FIG. 6 and corresponding to FIG. 14) which is a continuation of FIG. 12 and FIG. 13 showing part of a step in the method for manufacturing a semiconductor device according to Mode of Embodiment 1 of the present invention;

FIG. 16 is a view in cross section (corresponding to between C-C′ in FIG. 6 and corresponding to FIG. 17) which is a continuation of FIG. 14 and FIG. 15 showing part of a step in the method for manufacturing a semiconductor device according to Mode of Embodiment 1 of the present invention;

FIG. 17 is a view in cross section (corresponding to between B-B′ in FIG. 6 and corresponding to FIG. 16) which is a continuation of FIG. 14 and FIG. 15 showing part of a step in the method for manufacturing a semiconductor device according to Mode of Embodiment 1 of the present invention;

FIG. 18 is a partial plan view (corresponding to FIG. 19) which is a continuation of FIG. 16 and FIG. 17 showing part of a step in the method for manufacturing a semiconductor device according to Mode of Embodiment 1 of the present invention;

FIG. 19 is a view in cross section (corresponding to FIG. 18) between C-C′ in FIG. 18 showing part of a step in the method for manufacturing a semiconductor device according to Mode of Embodiment 1 of the present invention;

FIG. 20 is a view in cross section (corresponding to between C-C′ in FIG. 18) which is a continuation of FIG. 18 and FIG. 19 showing part of a step in the method for manufacturing a semiconductor device according to Mode of Embodiment 1 of the present invention;

FIG. 21 is a view in cross section (corresponding to between C-C′ in FIG. 18) which is a continuation of FIG. 20 showing part of a step in the method for manufacturing a semiconductor device according to Mode of Embodiment 1 of the present invention;

FIG. 22 is a view in cross section (corresponding to between B-B′ in FIG. 18 and corresponding to FIG. 21) which is a continuation of FIG. 20 showing part of a step in the method for manufacturing a semiconductor device according to Mode of Embodiment 1 of the present invention;

FIG. 23 is a view in cross section (corresponding to between C-C′ in FIG. 18) which is a continuation of FIG. 21 showing part of a step in the method for manufacturing a semiconductor device according to Mode of Embodiment 1 of the present invention;

FIG. 24 is a view in cross section (corresponding to between C-C′ in FIG. 18) which is a continuation of FIG. 23 showing part of a step in the method for manufacturing a semiconductor device according to Mode of Embodiment 1 of the present invention;

FIG. 25 is a view in cross section (corresponding to between A-A′ in FIG. 2) which is a continuation of FIG. 24 showing part of a step in the method for manufacturing a semiconductor device according to Mode of Embodiment 1 of the present invention;

FIG. 26 is a view in cross section (corresponding to between A-A′ in FIG. 2) which is a continuation of FIG. 25 showing part of a step in the method for manufacturing a semiconductor device according to Mode of Embodiment 1 of the present invention; and

FIG. 27 is a view in cross section (corresponding to between A-A′ in FIG. 2) which is a continuation of FIG. 26 showing part of a step in the method for manufacturing a semiconductor device according to Mode of Embodiment 1 of the present invention.

### MODE OF EMBODIMENT OF THE INVENTION

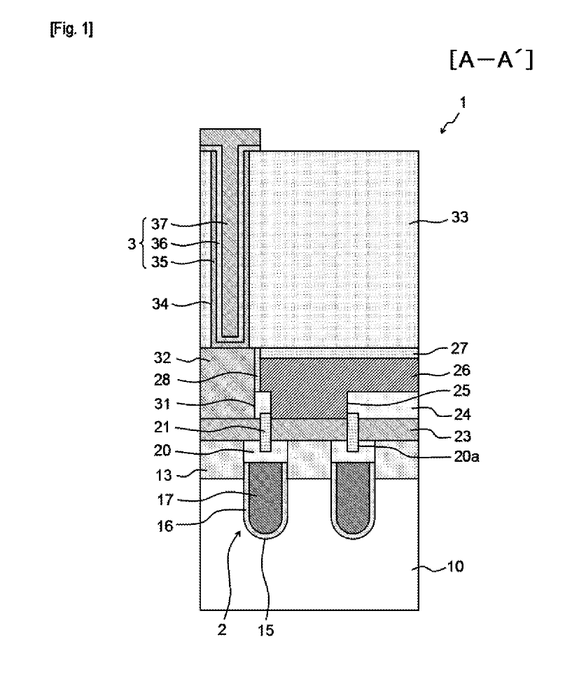

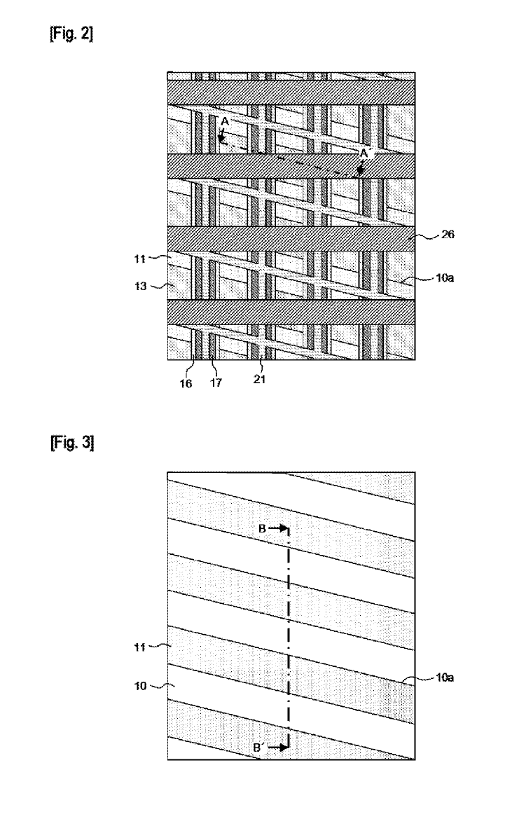

A semiconductor device according to a mode of embodiment of the present invention will be described with the aid of the figures. FIG. 1 is a view in cross section between A-A′ in FIG. 2 schematically showing the configuration of a semiconductor device according to Mode of Embodiment 1 of the present invention. FIG. 2 is a partial plan view (corresponding to FIG. 1) schematically showing the configuration of the semiconductor device according to Mode of Embodiment 1 of the present invention.

Mode of Embodiment 1 describes the example of a semiconductor device 1 in which the present invention is applied to a DRAM (Dynamic Random Access Memory) provided with a memory cell transistor formed by an n-type MOSFET structure. The semiconductor device 1 is a stacked structure in which an embedded gate-type MOS transistor 2 and a capacitor 3 are formed in a memory cell region of the DRAM (see FIG. 1). The semiconductor device 1 has element isolation regions 11 which extend in a predetermined direction (second direction) as shown in FIG. 2 and are arranged at predetermined intervals on a semiconductor substrate 10 (e.g. a P-type silicon substrate) in the memory cell region.

The element isolation regions 11 have an STI (Shallow Trench Isolation) structure in which an insulating film (e.g., a silicon dioxide film) is embedded in a trench 10a formed in the semiconductor substrate 10. The element isolation regions 11 electrically isolate the areas between adjacent active regions of the semiconductor substrate 10. The upper surfaces of the element isolation regions 11 are at a lower level than the upper surfaces of diffusion regions 13 (see FIG. 17). The active regions of the semiconductor substrate 10 are regions in which a memory cell transistor can be activated. The active regions of the semiconductor substrate 10 are arranged at predetermined intervals extending in a predetermined direction (the same second direction as the element isolation regions 11), and are demarcated by the element isolation regions 11.

Furthermore, embedded gate electrodes 17 for word lines are formed at predetermined intervals in the memory cell region extending in a predetermined direction (the longitudinal direction in FIG. 2; first direction) in such a way as to cross over (three-dimensionally intersect) the active regions of the semiconductor substrate 10 (see FIG. 2).

In addition, bit lines 26 are arranged at predetermined intervals extending in a direction orthogonal to the embedded gate electrodes 17 (the transverse direction in FIG. 2; third direction). Memory cells are formed in the regions in which the embedded gate electrodes 17 and the active regions of the semiconductor substrate 10 three-dimensionally intersect. The semiconductor device 1 has a 6F2 cell arrangement (F being the minimum processing dimension) in FIG. 1. Each memory cell has an embedded gate-type MOS transistor (2 in FIG. 1) and a capacitor (3 in FIG. 1).

A plurality of trenches 15 are formed at predetermined intervals extending in a predetermined direction (the longitudinal direction in FIG. 2; first direction) in the semiconductor substrate 10. The direction of extension of the trenches 15 (first direction) intersects the direction of extension of the element isolation regions 11 (second direction). The embedded gate electrodes 17 (e.g., TiN) are embedded at the lower part inside the trenches 15 (in such a way as not to fill the trenches 15) with the interposition of a gate insulating film 16 (e.g., a silicon dioxide film). The upper surfaces of the embedded gate electrodes 17 and the gate insulating film 16 are set in such a way as to be at a lower level than the upper surfaces of the diffusion regions 13. The embedded gate electrodes 17 constitute part of a word line and are used as gate electrodes in the memory cells.

The diffusion regions 13 are formed in an upper layer section between the trenches 15 in the active regions of the semiconductor substrate 10. The diffusion regions 13 are arranged adjacent to both sides of the trenches 15. The diffusion regions 13 are formed by implanting and diffusing impurity ions (e.g., N-type impurity, phosphorus) into the semiconductor substrate 10. The diffusion regions 13 on the capacitor side constitute source/drain electrodes electrically connected to a lower electrode 35 of the capacitor 3 via a corresponding conduction layer 23 and contact plug 32. The diffusion regions 13 on the bit line side constitute source/drain electrodes electrically connected to the bit lines 26 via the corresponding conduction layer 23.

An embedded insulating film 20 (e.g., a silicon dioxide film) is formed on the embedded gate electrodes 17 (including on the gate insulating film 16) inside the trenches 15 between the diffusion regions 13. The embedded insulating film 20 is also formed on the element isolation regions 11 between the diffusion regions 13 (see FIG. 17). The embedded insulating film 20 is formed as a mesh in such a way as to enclose and demarcate each diffusion region 13. The embedded insulating film 20 has a trench 20a (depression) in which the lower part of an isolation insulating film 21 (e.g., a silicon dioxide film) is embedded. The trench 20a is formed when the embedded insulating film 20 is deposited and follows the shape of the trenches between the diffusion regions 13. It should be noted that the trench 20a may be formed by patterning (etching) the embedded insulating film 20, as required. The trench 20a is also formed as a mesh in the same way as the embedded insulating film 20. The width of the isolation insulating film 21 is less than the width of the trench 15. The width of the isolation insulating film 21 is less than the width of the element isolation region 11. The isolation insulating film 21 is formed as a mesh and follows the shape of the trench 20a of the embedded insulating film 20. The isolation insulating film 21 extends (projects) above the upper surface of the embedded insulating film 20. The isolation insulating film 21 separates (partitions) the areas between adjacent conduction layers 23. The upper surface of the isolation insulating film 21 is set in such a way as to be at a higher level than the upper surface of the conduction layer 23. An insulating material having a different etching rate than the material employed for the embedded insulating film 20 is used for the isolation insulating film 21.

The conduction layer 23 (e.g., cobalt silicide) is formed on the embedded insulating film 20 and diffusion region 13 in each region enclosed by the isolation insulating film 21. The conduction layer 23 may be formed, for example, by depositing a silicon single crystal by means of epitaxial growth, sputtering cobalt (metal) on the deposited silicon single crystal, then forming cobalt silicide in which the silicon single crystal and cobalt have been silicided by means of annealing, and after this removing the unreacted cobalt using an H₂SO₄ chemical solution. The conduction layer 23 is formed at a lower level than the upper surface of the isolation insulating film 21. The conduction layer 23 electrically connects the corresponding diffusion region 13 and contact plug 32 or bit line 26. The conduction layer 23 is joined to the whole region of the upper surface of the corresponding diffusion region 13 and is joined to the whole region of the lower surface of the contact portion of the contact plug 32 or bit line 26.

An interlayer insulating film 24 (e.g., a silicon dioxide film) is formed on the conduction layer 23 including the isolation insulating film 21. A contact hole 25 communicating with the conduction layer 23 on the bit line side is formed in the interlayer insulating film 24. The bit line 26 (e.g., polysilicon) is formed at a predetermined portion on the interlayer insulating film 24 including the conduction layer 23 on the bit line side. The bit line 26 is joined to the conduction layer 23 on the corresponding bit line side over the whole region of the lower surface of the contact portion. A hard mask 27 (e.g., a silicon nitride film) is formed on the bit line 26. The side wall surfaces of the bit line 26 and the hard mask 27 are covered by a side wall insulating film 28.

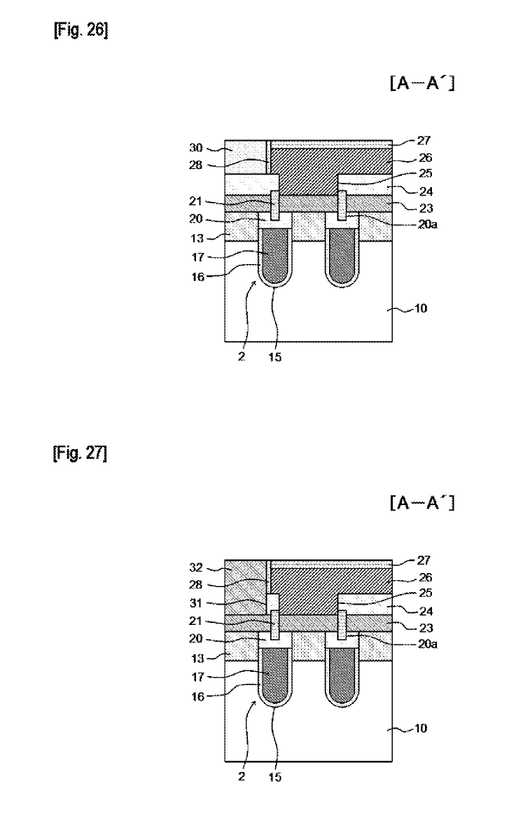

An interlayer insulating film 30 (e.g., a silicon dioxide film) is formed on the interlayer insulating film 24 between the side wall insulating films 28 (see FIG. 26). A contact hole 31 communicating with the conduction layer 23 on the capacitor side is formed in the interlayer insulating film 30 and the interlayer insulating film 24. The side wall insulating film 28 may be apparent at the side wall surface of the contact hole 31. The contact plug 32 (e.g., polysilicon) is embedded in the contact hole 31. The whole region of the lower surface of the contact plug 32 is joined to the corresponding conduction layer 23 on the capacitor side. The contact plug 32 and the bit line 26 are isolated at least by means of the side wall insulating film 28.

An interlayer insulating film 33 (e.g., a silicon dioxide film) is formed on the contact plug 32, interlayer insulating film 30, hard mask 27 and side wall insulating film 28. A contact hole 34 communicating with the contact plug 32 is formed in the interlayer insulating film 33. The lower electrode 35 (e.g., TiN) of the capacitor 3 is formed on the side wall surface of the interlayer insulating film 33 and on the upper surface of the contact plug 32 in the contact hole 34. The lower electrode 35 is formed in such a way as not to completely fill the contact hole 34. A capacitance insulating film 36 (e.g., ZrO₂) of the capacitor 3 is formed at a predetermined position on the interlayer insulating film 33 including the lower electrode 35 inside the contact hole 34. The capacitance insulating film 36 is formed in such a way as not to completely fill the contact hole 34 on the lower electrode 35. An upper electrode 37 (e.g., TiN) of the capacitor 3 is formed on the capacitance insulating film 36. The upper electrode 37 fills the capacitance insulating film 36 inside the contact hole 34. It should be noted that the example of the capacitor 3 described in Mode of Embodiment 1 is a cylinder-type capacitor in which only the inner wall surface (including the bottom surface) of the lower electrode 35 inside the contact hole 34 is used as an electrode, but this is not limiting and it may be changed to a crown-type capacitor in which the inner wall and the outer wall of the lower electrode are used as electrodes. An interlayer insulating film (not depicted) and a wiring layer (not depicted) are formed on the interlayer insulating film 33 including the upper electrode 37 and the capacitance insulating film 36.

The method for manufacturing a semiconductor device according to a mode of embodiment of the present invention will be described next with the aid of the figures. FIG. 3 to FIG. 27 are diagrams schematically showing the method for manufacturing a semiconductor device according to Mode of Embodiment 1 of the present invention.

Element isolation regions 11 for isolating active regions by lines and spaces are first of all formed on the surface of a semiconductor substrate 10 (e.g., a P-type silicon substrate) (step A1; see FIG. 3 and FIG. 4).

Here, the element isolation regions 11 can be formed in the following manner, for example. A silicon dioxide film (SiO₂; not depicted) and a masking silicon nitride film (Si₃N₄; not depicted) are first of all deposited in succession on the semiconductor substrate 10. After this, the silicon nitride film, silicon dioxide film and semiconductor substrate 10 are patterned in succession using lithography and dry etching, and trenches 10a arranged at predetermined intervals and extending in a predetermined direction (second direction) are formed. At this point, the surface of the active regions of the semiconductor substrate 10 are covered by the masking silicon nitride film with the silicon dioxide film interposed. After this, a silicon dioxide film is formed by subjecting the wall surface (including the bottom surface) of the trenches 10a to thermal oxidation. After this, an insulating film (e.g., an oxide film produced by HDP-CVD or a coating material such as a SOD (Spin-On Dielectric) material) is formed in such a way as to fill the trenches 10a. After this, the excess portions of the insulating film, masking silicon nitride film and silicon dioxide film which are not embedded in the trenches 10a are removed by means of CMP (Chemical Mechanical Polishing) until the semiconductor substrate 10 becomes apparent. STI (Shallow Trench Isolation)-type element isolation regions 11 can be formed in this way.

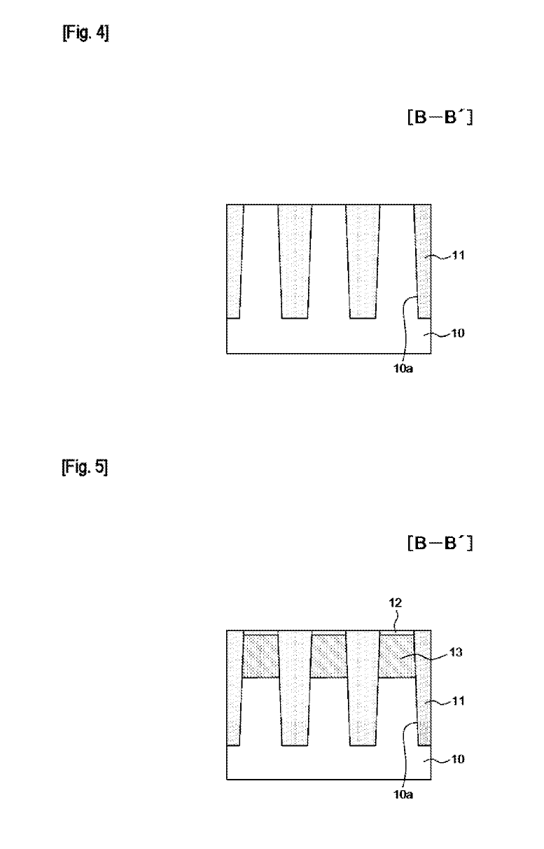

A silicon dioxide film 12 is then formed on the surface of the semiconductor substrate 10 exposed in the active regions, after which impurity (n-type phosphorus etc.) is implanted and diffused in the semiconductor substrate 10, whereby diffusion regions 13 are formed on the semiconductor substrate 10 (step A2; see FIG. 5).

Here, the silicon dioxide film 12 is formed to a thickness of the order of 10 nm by means of thermal oxidation, for example. Furthermore, the diffusion regions 13 may be formed in the following manner, for example. First of all, n-type impurity such as phosphorus, for example, is ion-implanted in the active regions (10a in FIG. 2) of the semiconductor substrate 10 through the silicon dioxide film 12 at a concentration of the order of 1×10¹³/cm³ and an acceleration energy of 20 keV. After this, heat treatment is carried out for 10 seconds at 980° C. under a nitrogen atmosphere, whereby the diffusion regions 13 in which n-type impurity is diffused are formed. The diffusion regions 13 function as part of a source/drain region of the embedded gate-type MOS transistor 2.

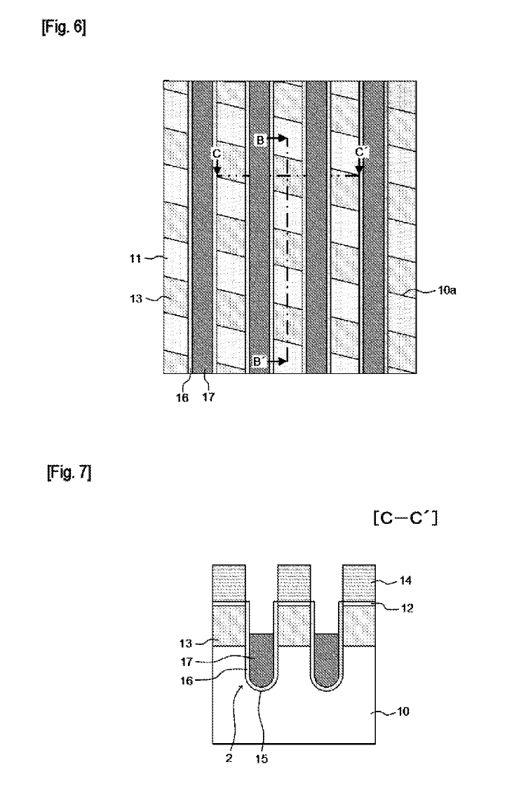

A hard mask 14 (e.g., a silicon nitride film having a thickness of the order of 150 nm) is formed on the silicon dioxide film 12, after which the hard mask 14 is subjected to line and space patterning (e.g., opening width around 40 nm, pitch around 90 nm) using lithography and dry etching, and after this the silicon dioxide film 12, diffusion regions 13 and semiconductor substrate 10 are patterned using the hard mask 14 as a mask by employing dry etching, thereby forming trenches 15 extending in a first direction orthogonal to the second direction and having a predetermined depth (a greater depth than the diffusion regions 13 and a smaller depth than the element isolation regions 11; e.g., around 140 nm from the upper surface of the diffusion regions 13), after which a gate insulating film 16 (e.g., a silicon dioxide film having a thickness of the order of 4 nm) is formed in such a way as to cover the wall surfaces of the trenches 15 (including the bottom surface and the wall surfaces of the diffusion regions 13 and the semiconductor substrate 10); following this, a metal film (e.g., TiN) constituting the embedded gate electrodes 17 is formed on the hard mask 14 including the gate insulating film 16 in such a way as to fill the trenches 15, after which part (the upper part) of the metal film is etched back and removed using a method such as dry etching and employing the hard mask 14 as a mask, whereby the embedded gate electrodes 17 constituting word lines are formed in such a way that the upper surfaces of the embedded gate electrodes 17 are at a lower level than the upper surfaces of the diffusion regions 13 (step A3; see FIG. 6 and FIG. 7).

Here, the hard mask 14 and the silicon dioxide film 12 may be patterned by means of anisotropic etching, for example. Furthermore, the diffusion regions 13 and semiconductor substrate 10 may be patterned by means of anisotropic dry etching employing a gas in which H₂ is added to a mixed gas comprising CF₄ and Ar and using the hard mask 14 and silicon dioxide film 12 as a mask, for example. The patterning of the diffusion regions 13 and semiconductor substrate 10 also involves patterning part of the element isolation regions 11 below the trenches 15 to a predetermined depth. It should be noted that the trenches 15 are formed in a line pattern extending in a predetermined direction intersecting the active regions 10a (the longitudinal direction in FIG. 6; first direction).

Furthermore, the gate insulating film 16 may be formed by subjecting the wall surface (including the bottom surface) of the trenches 15 to thermal oxidation by means of ISSG (In-Situ Steam Generation), for example. In addition, the metal film constituting the embedded gate electrodes 17 may be formed by means of thermal CVD employing TiCl₄ gas and NH₃ gas.

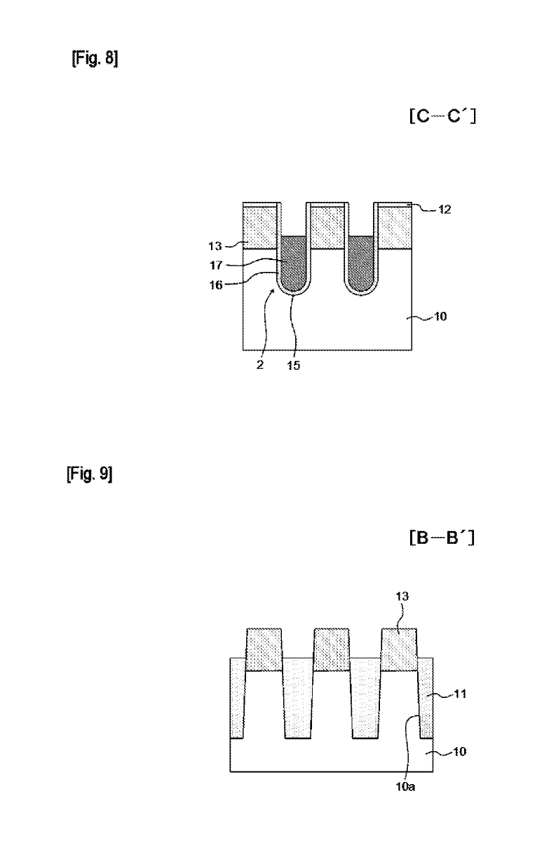

The hard mask 14 is then selectively removed by means of wet etching or chemical dry etching (step A4; see FIG. 8).

Part (the upper part) of the element isolation regions 11 is then removed by means of wet etching or chemical dry etching in such a way that the upper surfaces of the element isolation regions 11 are at a lower level than the upper surfaces of the diffusion regions 13 (step A5; see FIG. 9).

Here, the silicon dioxide film 12 and the gate insulating film 16 (exposed portion) which is made of the same material as the element isolation region 11 (e.g. a silicon dioxide film) are also removed in step A5. Furthermore, the upper surfaces of the element isolation regions 11 are preferably at the same depth as the upper surfaces of the embedded gate electrodes 17 (or at a comparable depth).

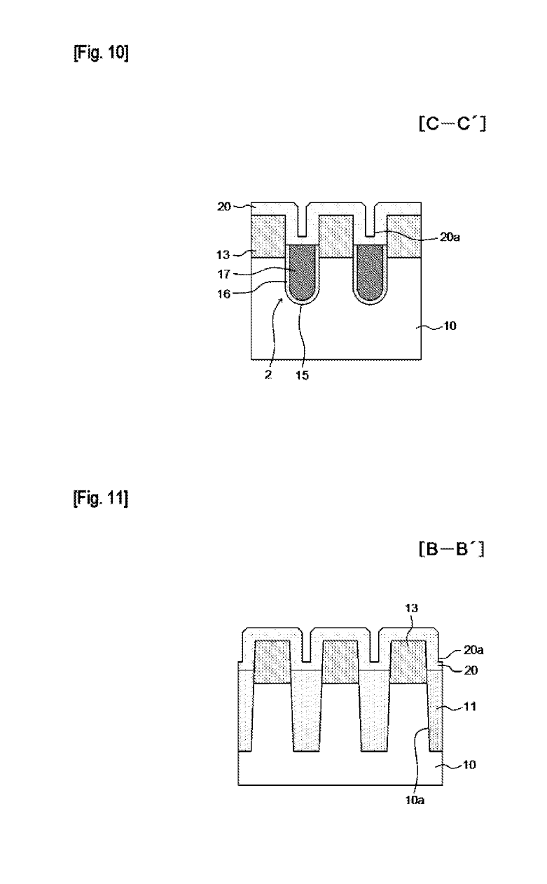

The embedded insulating film 20 (e.g., a silicon dioxide film) is then deposited on the element isolation regions 11, diffusion regions 13, gate insulating film 16 and embedded gate electrodes 17 (step A6; see FIG. 10 and FIG. 11). Here, the embedded insulating film 20 is deposited in step A6 in such a way as not to fill the trenches 10a, 15 (spaces) between the diffusion regions 13. By doing so, mesh-like trenches 20a (depressions) are formed on the embedded insulating film 20 between the diffusion regions 13.

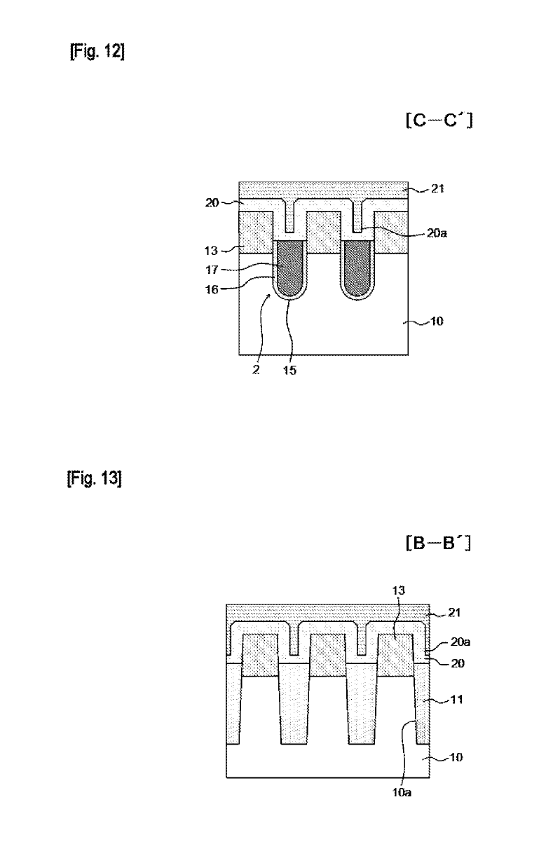

The isolation insulating film 21 (e.g., a silicon nitride film) is then deposited on the embedded insulating film 20 until the trenches 20a in the embedded insulating film 20 are filled (step A7; see FIG. 12 and FIG. 13). Here, a different material than that of the embedded insulating film 20 (a material having a different etching rate) is used for the isolation insulating film 21.

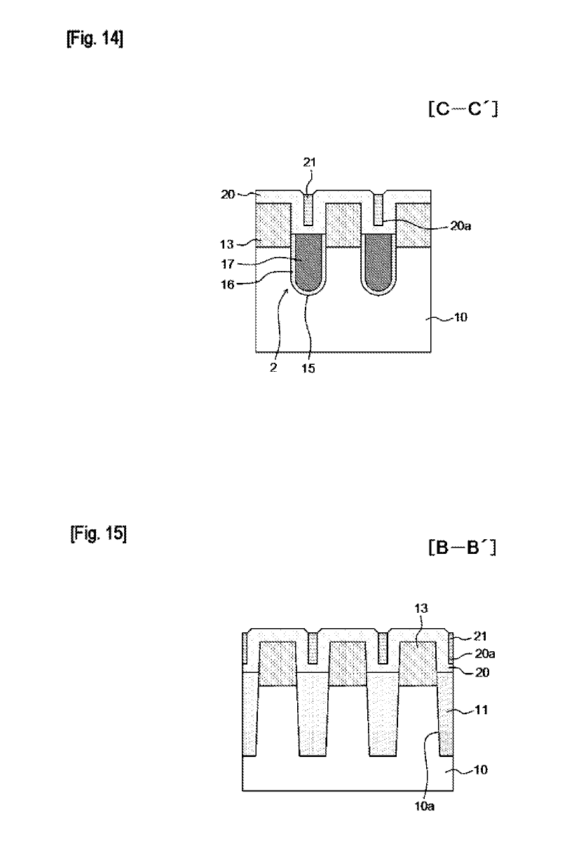

The isolation insulating film 21 is then selectively etched back until the upper surface of at least the embedded insulating film 20 (excluding the trenches 20a) becomes apparent (the upper surface of the isolation insulating film 21 may be at a lower level than the upper surface of the embedded insulating film 20) (step A8; see FIG. 14 and FIG. 15). As a result, the mesh-like isolation insulating film 21 is formed in the mesh-like trenches 20a (depressions) on the embedded insulating film 20 between the diffusion regions 13.

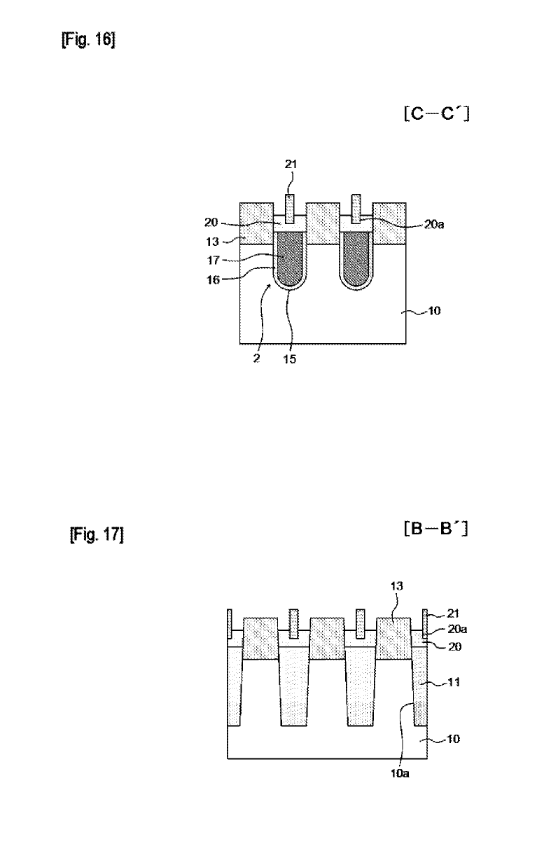

The embedded insulating film 20 is then selectively etched back until the diffusion regions 13 become apparent (or possibly until the upper surface of the embedded insulating film 20 is at a lower level than the upper surfaces of the diffusion regions 13) (step A9; see FIG. 16 and FIG. 17). As a result, the isolation insulating film 21 projects beyond the upper surfaces of the embedded insulating film 20 and the diffusion regions 13. It should be noted that the upper surface of the embedded insulating film 20 is at a higher level than the bottom surface of the trenches 20a.

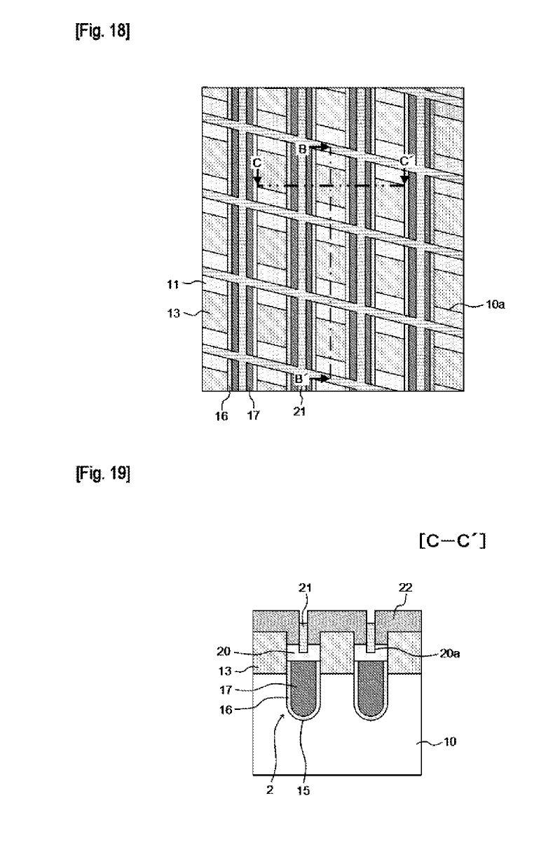

A selective epitaxial layer 22 (silicon single crystal) is then formed (deposited) by means of selective epitaxial growth on the surface of the diffusion regions 13 (step A10; see FIG. 18 and FIG. 19). Here, the selective epitaxial layer 22 is formed until the gap (trench) between the diffusion regions 13 and the isolation insulating film 21 on the embedded insulating film 20 is filled. The selective epitaxial layer 22 may completely cover the isolation insulating film 21.

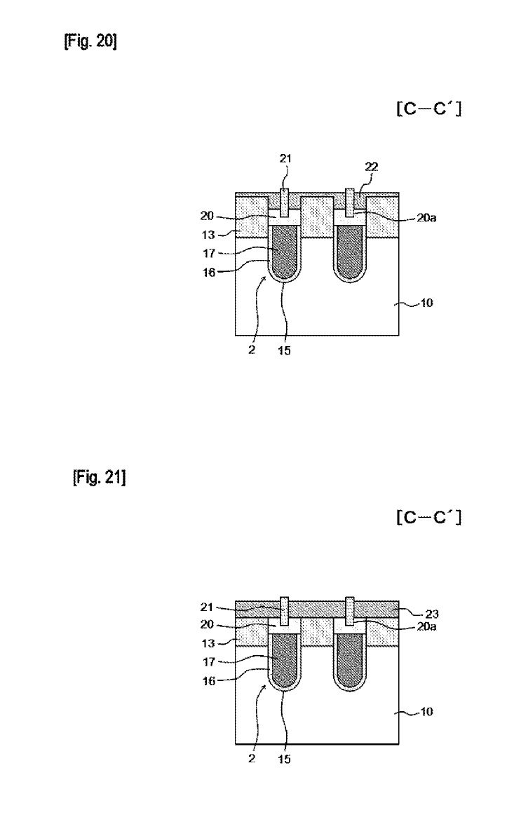

The selective epitaxial layer 22 is then etched back until the upper surface of the selective epitaxial layer 22 is at a lower level than the upper surface of the isolation insulating film 20 (step A11; see FIG. 20).

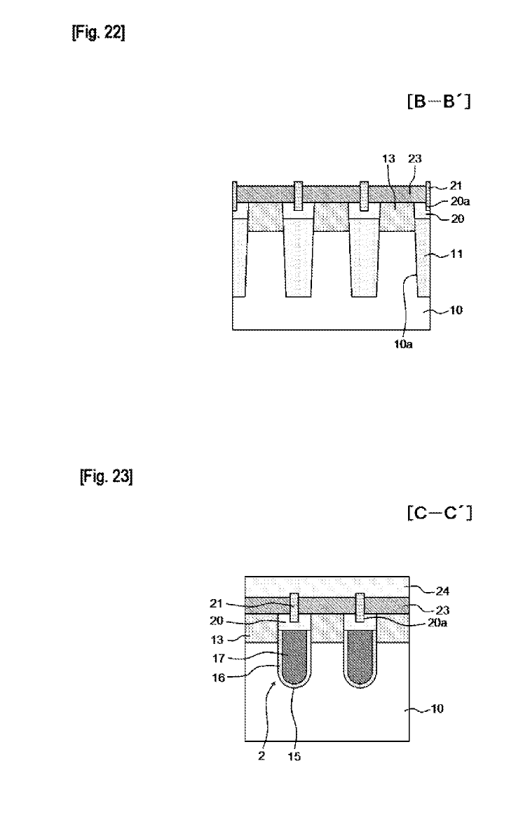

A metal (not depicted; e.g., cobalt) is then sputtered on the selective epitaxial layer (22 in FIG. 20), after which annealing is carried out at between 600 and 700° C., whereby the conduction layer 23 in which the selective epitaxial layer (22 in FIG. 20) is silicided is formed, and the unreacted metal is removed using an H₂SO₄ chemical solution (step A12; see FIG. 21 and FIG. 22).

Here, in step A12, the metal (cobalt) is sputtered and annealed in such a way that the upper surface of the conduction layer 23 is at a lower level than the upper surface of the isolation insulating film 21. Furthermore, the annealing is carried out in such a way that the lower surface of the conduction layer 23 is at a comparable level with (or possibly at the same level as) the upper surface of the embedded insulating film 20. In addition, the conduction layer 23 includes not only the selective epitaxial layer (22 in FIG. 20) and the metal which have been silicided, but also the diffusion regions 13 and the metal which have been silicided.

An interlayer insulating film 24 (e.g., a silicon dioxide film) for bit contact is then deposited on the conduction layer 23 including the isolation insulating film 21 (step A13; see FIG. 23).

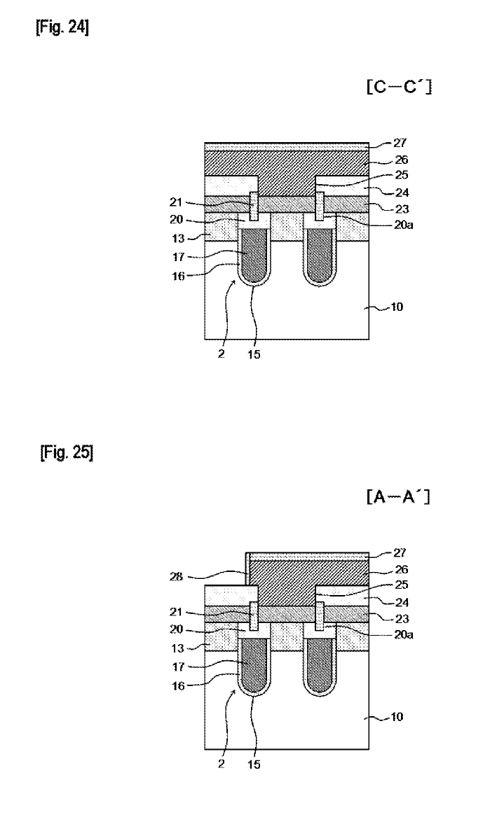

A contact hole 25 communicating with the conduction layer 23 for the bit line 26 is then formed on the interlayer insulating film 24 using lithography and dry etching, after which a conductor film (e.g., polysilicon) for the bit line 26 is deposited until the contact hole 25 is filled, a hard mask 27 (e.g., a silicon nitride film) is then deposited, after which the hard mask 27 is patterned using lithography and dry etching, and following this the conductor film is patterned using the hard mask 27 as a mask and employing dry etching, whereby the bit line 26 is formed (step A14; see FIG. 24).

An insulating film (e.g., a silicon nitride film) for a side wall insulating film 28 is then formed on the interlayer insulating film 24 including the bit line 26 and the hard mask 27, after which the side wall insulating film 28 is formed by means of etch back (step A15; see FIG. 25).

An interlayer insulating film 30 (e.g., a silicon dioxide film) is then deposited on the interlayer insulating film 24 including the side wall insulating film 28 and the hard mask 27, after which the interlayer insulating film 30 is ground and removed until the hard mask 27 becomes apparent (step A16; see FIG. 26).

A contact hole 31 communicating with the conduction layer 23 on the capacitor 3 side is then formed in the interlayer insulating film (30 in FIG. 26) and the interlayer insulating film 24 using lithography and dry etching, after which a contact plug 32 (e.g., polysilicon) is formed inside the contact hole 31 (step A17; see FIG. 27).

Here, the contact plug 32 may be formed, for example, by depositing polysilicon doped with phosphorus at a concentration of 1×10²⁰/cm³ to a thickness of the order of 80 nm in such a way as to fill the contact hole 31, using LP-CVD, and then by grinding and removing the polysilicon by means of CMP until the hard mask 27 becomes apparent.

An interlayer insulating film 33 (e.g., a silicon dioxide film) is then deposited on the interlayer insulating film (30 in FIG. 26) including the contact plug 32, hard mask 27 and side wall insulating film 28, after which a contact hole 34 communicating with the contact plug 32 is formed in the interlayer insulating film 33, then a lower electrode 35 (e.g., TiN) is formed covering the wall surface of the interlayer insulating film 33 inside the contact hole 34 and the upper surface of the contact plug 32, after which a capacitance insulating film 36 is formed on the interlayer insulating film 33 including the lower electrode 35, then an upper electrode 37 (e.g., TiN) is formed on the capacitance insulating film 36 in such a way as to fill the contact hole 34, after which the upper electrode 37 and the capacitance insulating film 36 are patterned using lithography and dry etching (step A18; see FIG. 1). The capacitor 3 can be formed as a result.

Here, zirconium oxide (ZrO₂), aluminum oxide (Al₂O₃), hafnium oxide (HfO₂) or a laminated film comprising the abovementioned compounds may be used for the capacitance insulating film 36, for example.

Finally, an interlayer insulating film (not depicted) and a wiring layer (not depicted) are formed on the interlayer insulating film 33 including the upper electrode 37 and the capacitance insulating film 36 (step A19). A semiconductor device 1 having a DRAM memory cell is completed as a result.

It should be noted that in parallel with the processing of FIG. 3 to FIG. 27 and FIG. 1, a transistor in a peripheral circuit region disposed around the memory cell region, a contact for connecting to the transistor in the peripheral circuit region, a contact to the word line and a contact to the bit line are formed, and a cylinder plate electrode and upper wiring etc. are further formed, and used as a DRAM, although this is not depicted.

According to the mode of embodiment, the conduction layer 23 on the diffusion regions 13 partitioned (isolated) by the isolation insulating film 21 is present up to a region on the embedded gate electrodes 17 and on the element isolation regions 11, and as a result it is possible to broaden the contact area between the contact plug 32 for connecting the capacitor 3 and the diffusion regions 13 through the conduction layer 23. Furthermore, according to the mode of embodiment, the conduction layer 23 on the diffusion regions 13 is isolated by the isolation insulating film 21, and as a result it is possible to enlarge the short-circuit margin between the diffusion regions 13.

It should be noted that Patent Document 1 does not indicate that a conduction layer is formed inside a region enclosed by an isolation insulating film or that a diffusion region and a contact plug are connected by way of the conduction layer, as is described in the present invention.

Furthermore, where reference symbols are appended to the figures of this application, these are solely to aid an understanding and are not intended to limit the invention to the mode shown in the figures.

In addition, modifications and adjustments may be made to the mode of embodiment and exemplary embodiments in accordance with the basic technical concept of the present invention, within the context of the disclosure of the present invention in its entirety (including the claims and figures). Furthermore, a large variety of the various elements disclosed (including elements in the claims, elements in the mode of embodiment and exemplary embodiments, and elements in the figures etc.) may be combined or selected within the context of the claims of the present invention. That is to say, the present invention of course includes a number of variants and alterations which could be achieved by a person skilled in the art in accordance with the technical concept and the full disclosure including the claims and figures. Furthermore, for the numerical values and numerical value ranges given in this application, although not explicitly stated, these should be deemed to describe any intermediate value, a low-order value or a small range.

(Additional Notes)

According to a first aspect of the present invention, the semiconductor device is characterized in that it is provided with: a semiconductor substrate having a plurality of first trenches formed extending in a first direction; an embedded gate electrode which is embedded at the lower part of the first trenches with a gate insulating film interposed; an embedded insulating film which is embedded on the embedded gate electrode in the first trenches; an isolation insulating film which is provided on the embedded insulating film and has a smaller width than the first trenches; a diffusion region which is provided adjacent to the first trenches on the semiconductor substrate; a conduction layer in contact with the diffusion region; and a contact plug in contact with the conduction layer, the conduction layer also being disposed on the embedded insulating film on the embedded gate electrode and also being partitioned by the isolation insulating film.

Preferably, in the semiconductor device according to the present invention, the semiconductor substrate has a plurality of second trenches formed extending in a second direction intersecting the first direction, and also has an element isolation region in which an insulating film is embedded at the lower part of the second trenches, the embedded insulating film is also embedded on the element isolation region in the second trenches, the isolation insulating film has a smaller width than the second trenches, and the conduction layer is also disposed on the embedded insulating film on the element isolation region and is also enclosed by the isolation insulating film.

Preferably, the semiconductor device according to the present invention is provided with: another diffusion region which is provided adjacently on the semiconductor substrate on the opposite side to the abovementioned diffusion region side of the first trenches; another conduction layer in contact with the other diffusion region; and a bit line in contact with the other conduction layer, the other conduction layer also being disposed on the embedded insulating film on the embedded gate electrode, and the isolation insulating film isolating the abovementioned conduction layer and the other conduction layer which are adjacent.

Preferably, the semiconductor device according to the present invention is provided with a side wall insulating film covering the side surface of the bit line, the bit line being insulated from the contact plug by means of the side wall insulating film.

Preferably, in the semiconductor device according to the present invention, the embedded insulating film has, in the center of the upper surface, a third trench which is smaller in width than the first trenches, the third trench is formed in the direction of extension of the embedded insulating film, and the isolation insulating film is embedded in the third trench and projects further upward than the upper surface of the embedded insulating film.

In the semiconductor device according to the present invention, the upper surface of the isolation insulating film is preferably at a higher level than the upper surface of the conduction layer.

In the semiconductor device according to the present invention, the conduction layer is preferably a layer in which at least silicon formed by selective epitaxial growth is silicided.

In the semiconductor device according to the present invention, the conduction layer preferably includes a portion in which part of the diffusion region is silicided.

In the semiconductor device according to the present invention, the embedded gate electrode preferably constitutes a part of a word line.

Preferably, in the semiconductor device according to the present invention, the conduction layer is joined to the whole region of the upper surface of the diffusion region and is joined to the whole region of the lower surface of the contact plug.

According to a second aspect of the present invention, a method for manufacturing a semiconductor device is characterized in that it comprises the following steps: a step in which a diffusion region is formed on the upper part of a semiconductor substrate; a step in which a plurality of first trenches which extend in a first direction and have a greater depth than the diffusion region are formed on the semiconductor substrate including the diffusion region; a step in which an embedded gate electrode which is embedded with a gate insulating film interposed is formed inside the first trenches; a step in which the upper part of the embedded gate electrode inside the first trenches is removed; a step in which an embedded insulating film is deposited on the diffusion region including the embedded gate electrode inside the first trenches, in such a way that the first trenches are not filled; a step in which an isolation insulating film is deposited on the embedded insulating film in such a way that the first trenches are filled; a step in which the upper part of the isolation insulating film is selectively removed until the embedded insulating film becomes apparent; a step in which the upper part of the embedded insulating film is selectively removed until the diffusion region becomes apparent while the isolation insulating film remains; a step in which a plurality of conduction layers partitioned by means of the isolation insulating film are formed on the diffusion region including the embedded insulating film; a step in which a first interlayer insulating film is formed on the conduction layer including the isolation insulating film; a step in which a first contact hole communicating with a first conduction layer from among the plurality of conduction layers is formed in the first interlayer insulating film; and a step in which a contact plug is formed inside the first contact hole.

Preferably, in the method for manufacturing a semiconductor device according to the present invention, before the step in which the diffusion region is formed, the following steps are included: a step in which a plurality of second trenches extending in a second direction intersecting the first direction are formed in the semiconductor substrate, and a step in which an element isolation region in which an insulating film is embedded is formed inside the second trenches; after the step in which the upper part of the embedded gate electrode is removed and before the step in which the embedded insulating film is deposited, a step in which the upper part of the element isolation region inside the second trenches is selectively removed is included; in the step in which the embedded insulating film is deposited, the embedded insulating film is deposited on the element isolation region inside the second trenches in such a way that the second trenches are not filled; and in the step in which the isolation insulating film is deposited, the isolation insulating film is deposited on the embedded insulating film in such a way that the second trenches are filled.

Preferably, in the method for manufacturing a semiconductor device according to the present invention, after the step in which the conduction layer is formed and before the step in which the first interlayer insulating film is formed, the following steps are included: a step in which a second interlayer insulating film is formed on the conduction layer including the isolation insulating film, a step in which a second contact hole communicating with a second conduction layer from among the plurality of conduction layers is formed on the second interlayer insulating film, and a step in which a bit line is formed at a predetermined position on the second interlayer insulating film including the second contact hole; in the step in which the first interlayer insulating film is formed, the first interlayer insulating film is formed on the second interlayer insulating film including the bit line; and in the step in which the first contact hole is formed, the first contact hole is formed in the first interlayer insulating film and the second interlayer insulating film.

Preferably, in the method for manufacturing a semiconductor device according to the present invention, after the step in which the bit line is formed and before the step in which the first interlayer insulating film is formed, a step in which a side wall insulating film covering the side surface of the bit line is formed is included; in the step in which the first interlayer insulating film is formed, the first interlayer insulating film is formed on the second interlayer insulating film including the side wall insulating film and the bit line; and in the step in which the first contact hole is formed, the first contact hole is formed by selectively etching the first interlayer insulating film and the second interlayer insulating film.

Preferably, in the method for manufacturing a semiconductor device according to the present invention, in the step in which the upper part of the embedded insulating film is removed, the upper part of the embedded insulating film is removed until the isolation insulating film projects further upward than the upper surface of the embedded insulating film.

Preferably, in the method for manufacturing a semiconductor device according to the present invention, in the step in which the conduction layer is formed, the conduction layer is formed in such a way that the upper surface of the isolation insulating film is at a higher level than the upper surface of the conduction layer.

Preferably, in the method for manufacturing a semiconductor device according to the present invention, in the step in which the conduction layer is formed, a silicon single crystal is deposited by means of selective epitaxial growth on the diffusion region including the embedded insulating film, a metal is sputtered on the silicon single crystal deposited, after which the conduction layer comprising silicide in which the silicon single crystal and the metal have been silicided by annealing is formed, and after this the unreacted metal is removed using an H₂SO₄ chemical solution.

Preferably, in the method for manufacturing a semiconductor device according to the present invention, in the step in which the conduction layer is formed, part of the diffusion region is also silicided during the abovementioned siliciding.

Preferably, in the method for manufacturing a semiconductor device according to the present invention, in the step in which the conduction layer is formed, after the metal has been sputtered and before annealing is carried out, the upper part of the isolation insulating film is exposed by etching back the silicon single crystal.

In the method for manufacturing a semiconductor device according to the present invention, a step in which a capacitor connected to the contact plug is formed is preferably included after the step which the contact plug is formed.

### KEY TO SYMBOLS

1 . . . Semiconductor device
2 . . . Embedded gate-type MOS transistor
3 . . . Capacitor
10 . . . Semiconductor substrate
10a . . . Trench (second trench)
11 . . . Element isolation region
12 . . . Silicon dioxide film
13 . . . Diffusion region
14 . . . Hard mask (for forming word line)
15 . . . Trench (first trench)
16 . . . Gate insulating film
17 . . . Embedded gate electrode (word line)
20 . . . Embedded insulating film
20a . . . Trench (13)
21 . . . Isolation insulating film
22 . . . Selective epitaxial layer
23 . . . Conduction layer
24 . . . Interlayer insulating film
25 . . . Contact hole
26 . . . Bit line
27 . . . Hard mask (for forming bit line)
28 . . . Side wall insulating film
30 . . . Interlayer insulating film
31 . . . Contact hole
32 . . . Contact plug
33 . . . Interlayer insulating film
34 . . . Contact hole
35 . . . Lower electrode
36 . . . Capacitance insulating film
37 . . . Upper electrode

1. A semiconductor device comprising:
a semiconductor substrate having a plurality of first trenches formed extending in a first direction;
an embedded gate electrode which is embedded at the lower part of the first trenches with a gate insulating film interposed;
an embedded insulating film which is embedded on the embedded gate electrode in the first trenches;
an isolation insulating film which is provided on the embedded insulating film and has a smaller width than the first trenches;
a diffusion region which is provided adjacent to the first trenches on the semiconductor substrate;
a conduction layer in contact with the diffusion region; and
a contact plug in contact with the conduction layer, the conduction layer also being disposed on the embedded insulating film on the embedded gate electrode and also being partitioned by the isolation insulating film.

2. The semiconductor device of claim 1, wherein the semiconductor substrate has a plurality of second trenches formed extending in a second direction intersecting the first direction, and also has an element isolation region in which an insulating film is embedded at the lower part of the second trenches, the embedded insulating film is also embedded on the element isolation region in the second trenches, the isolation insulating film has a smaller width than the second trenches, and the conduction layer is also disposed on the embedded insulating film on the element isolation region and is also enclosed by the isolation insulating film.

3. The semiconductor device of claim 1, comprising:
another diffusion region which is provided adjacently on the semiconductor substrate on the opposite side to the abovementioned diffusion region side of the first trenches;
another conduction layer in contact with the other diffusion region; and
a bit line in contact with the other conduction layer, the other conduction layer also being disposed on the embedded insulating film on the embedded gate electrode, and the isolation insulating film isolating the abovementioned conduction layer and the other conduction layer which are adjacent.

4. The semiconductor device of claim 3, comprising a side wall insulating film covering the side surface of the bit line, the bit line being insulated from the contact plug by means of the side wall insulating film.

5. The semiconductor device of claim 1, wherein the embedded insulating film has, in the center of the upper surface, a third trench which is smaller in width than the first trenches, the third trench is formed in the direction of extension of the embedded insulating film, and the isolation insulating film is embedded in the third trench and projects further upward than the upper surface of the embedded insulating film.

6. The semiconductor device of claim 1, wherein the upper surface of the isolation insulating film is at a higher level than the upper surface of the conduction layer.

7. The semiconductor device of claim 1, wherein the conduction layer is a layer in which at least silicon formed by selective epitaxial growth is silicided.

8. The semiconductor device of claim 7, wherein the conduction layer includes a portion in which part of the diffusion region is silicided.

9. The semiconductor device of claim 1, wherein the embedded gate electrode constitutes a part of a word line.

10. The semiconductor device of claim 1, wherein the conduction layer is joined to the whole region of the upper surface of the diffusion region and is joined to the whole region of the lower surface of the contact plug.

11. A method for manufacturing a semiconductor device comprising:
forming a diffusion region on the upper part of a semiconductor substrate;
forming a plurality of first trenches which extend in a first direction and have a greater depth than the diffusion region on the semiconductor substrate including the diffusion region;
an embedded gate electrode which is embedded with a gate insulating film interposed is formed inside the first trenches;
removing the upper part of the embedded gate electrode inside the first trenches;
depositing an embedded insulating film on the diffusion region including the embedded gate electrode inside the first trenches, in such a way that the first trenches are not filled;
depositing an isolation insulating film on the embedded insulating film in such a way that the first trenches are filled;
selectively removing the upper part of the isolation insulating film until the embedded insulating film becomes apparent;
selectively removing the upper part of the embedded insulating film until the diffusion region becomes apparent while the isolation insulating film remains;
forming a plurality of conduction layers partitioned by means of the isolation insulating film on the diffusion region including the embedded insulating film;
forming a first interlayer insulating film on the conduction layer including the isolation insulating film;
forming a first contact hole communicating with a first conduction layer from among the plurality of conduction layers in the first interlayer insulating film; and
forming a contact plug inside the first contact hole.

12. The method of claim 11, comprising, before forming the diffusion region:
forming a plurality of second trenches extending in a second direction intersecting the first direction in the semiconductor substrate; and
forming an element isolation region in which an insulating film is embedded inside the second trenches,
after removing the upper part of the embedded gate electrode and before depositing the embedded insulating film, selectively removing the upper part of the element isolation region inside the second trenches,
wherein depositing the embedded insulating film comprises depositing the embedded insulating film on the element isolation region inside the second trenches in such a way that the second trenches are not filled, and
depositing the isolation insulating film comprises depositing the isolation insulating film on the embedded insulating film in such a way that the second trenches are filled.

13. The method of claim 11, comprising, after forming the conduction layer and before forming the first interlayer insulating film:
forming a second interlayer insulating film on the conduction layer including the isolation insulating film;
forming a second contact hole communicating with a second conduction layer from among the plurality of conduction layers on the second interlayer insulating film; and
forming a bit line at a predetermined position on the second interlayer insulating film including the second contact hole,
wherein forming the first interlayer insulating film comprises forming the first interlayer insulating film on the second interlayer insulating film including the bit line, and
forming the first contact hole comprises forming the first contact hole in the first interlayer insulating film and the second interlayer insulating film.

14. The method of claim 13, comprising, after forming the bit line and before forming the first interlayer insulating film, forming a side wall insulating film covering the side surface of the bit line,
wherein forming the first interlayer insulating film comprises forming the first interlayer insulating film on the second interlayer insulating film including the side wall insulating film and the bit line, and
forming the first contact hole comprises forming the first contact hole by selectively etching the first interlayer insulating film and the second interlayer insulating film.

15. The method of claim 11, wherein, removing the upper part of the embedded insulating film comprises removing the upper part of the embedded insulating film until the isolation insulating film projects further upward than the upper surface of the embedded insulating film.

16. The method of claim 11, wherein, forming the conduction layer comprises forming the conduction layer in such a way that the upper surface of the isolation insulating film is at a higher level than the upper surface of the conduction layer.

17. The method of claim 11, wherein, forming the conduction layer comprises depositing a silicon single crystal by means of selective epitaxial growth on the diffusion region including the embedded insulating film, a metal is sputtered on the silicon single crystal deposited, after which the conduction layer comprising silicide in which the silicon single crystal and the metal have been silicided by annealing is formed, and after this the unreacted metal is removed using an H₂SO₄ chemical solution.

18. The method of claim 17, wherein, forming the conduction layer comprises siliciding part of the diffusion region during the abovementioned siliciding.

19. The method of claim 17, wherein, forming the conduction layer comprises, after the metal has been sputtered and before annealing is carried out, exposing the upper part of the isolation insulating film by etching back the silicon single crystal.

20. The method of claim 11, comprising forming a capacitor connected to the contact plug after forming the contact plug.
